(19) United States
(12) Patent Application Publication
(10) Pub. No.: US 2004/0043524 A1
(43) Pub. Date: Mar. 4, 2004

(54) Method for fabricating light emitting diode with transparent substrate

(75) Inventors: Wen-Chieh Huang, Taipei (TW); Wen-Huang Tseng, Taipei (TW); Chi-Wei Lu, Taipei (TW)

Correspondence Address: QUINTERO LAW OFFICE, 1617 BROADWAY, 3RD FLOOR, SANTA MONICA, CA, 90404, US

(73) Assignee: Arima Optoelectronics Corp.

(21) Appl. No.: 10/443,584

(22) Filed: May 22, 2003

(30) Foreign Application Priority Data
Aug. 28, 2002 (TW) 91119508

(51) Int. Cl. H01L 21/00

(52) U.S. Cl. 438/26; 438/46; 438/47

(57) ABSTRACT

A method for fabricating a light emitting diode with transparent substrate. The method comprises forming a first type cladding layer on a substrate, forming an active layer on the first type cladding layer, forming a second type cladding layer on the active layer, forming a second type transparent semiconductor layer on the second type cladding layer to serve as the transparent substrate, removing the substrate, and forming a first type contact layer on the surface of the first type cladding layer previously connected to the substrate. The transparent substrate does not absorb the emitted light, thereby the light emitting efficiency is increased by as much as double, and thus the performance of opto-electronic devices is improved.

### BACKGROUND OF THE INVENTION

1. Field of the Invention

The present invention relates to the field of light emitting diodes. More particularly, the invention relates to a method for fabricating a light emitting diode with transparent substrate.

2. Description of the Related Art

Light emitting diodes (LEDs) are semiconductor devices able to convert electricity to light with several advantages such as small size, long life, low driving voltage, quick response, and others. Being capable of fulfilling the requirements of light, and thin and small profiles for a variety of equipment, LEDs have become indispensable.

FIG. 1 shows a III-V group semiconductor light emitting device. The light emitting device 1 comprises a GaAs substrate 2. A n-type cladding layer 3 based on GaInP is formed on the GaAs substrate 2. An active layer 4 is then formed on the n-type GaInP layer 3. A p-type cladding layer 5 based on GaInP is formed on the active layer 4. A p-type GaP layer 6 is then formed on the p-type GaInP layer 5 to serve as a current spreading layer.

The operating principal of LEDs introduces a current through the active layer 4 at p-n junction and thereby emits the light. To increase the light emitting efficiency, in addition to raising the crystallinity and enhancing quantum efficiency, improvement of light extraction technique is also applicable.

Generally the reflectivity of semiconductor LEDs is higher than the exterior fabricating materials, therefore most of the emitted light of the active layer is totally reflected at the interface between the semiconductor and the exterior fabricating materials (such as epoxy resin), and then absorbed by the active layer, electrode, substrate and others. Thus the exterior light extraction ratio of LEDs is far lower than the interior quantum efficiency. With current techniques, the exterior light extraction ratio of LEDs is only about 30%.

The LED shown in FIG. 1, GaAs, capable of absorbing visible light, is used as the substrate, thus the exterior light extraction ratio is reduced.

To reduce light absorption of substrates, research aimed at LEDs with transparent substrate have resulted in, for example, LEDs with transparent substrate fabricated by wafer-bonding consisting of removing the GaAs substrate after crystal-epitaxial of the LED, and applying a GaP substrate with high pressure at high temperature on the surface previously connected to the GaAs substrate whereby the GaP substrate is bonded with the LED. With the transparent substrate, the light extraction ratio can be doubled.

The above-mentioned method is applicable for an LED with transparent substrate, however, the wafer-bonding step requires high temperature and high pressure, therefore complicating the process.

### SUMMARY OF THE INVENTION

Thus, the purpose of the invention is to provide a method for fabricating an LED with transparent substrate without requiring a wafer-bonding step whereby the light emitting efficiency is double that of an LED without transparent substrate, thereby improving the performance of opto-electronic devices.

To achieve the purpose, the invention provides a method for fabricating an LED with transparent substrate, which comprises forming a first type cladding layer on a GaAs substrate, forming an active layer on the first type cladding layer, forming a second type cladding layer on the active layer, forming a second type GaP layer on the second type cladding layer to serve as the transparent substrate, forming a second type contact layer on the second type GaP layer, removing the GaAs substrate, and forming a first type contact layer on the surface of the first type cladding layer previously connected to the GaAs substrate.

### BRIEF DESCRIPTION OF THE DRAWINGS

The following detailed description, given by way of example and not intended to limit the invention solely to the embodiment described herein, will best be understood in conjunction with the accompanying drawings, in which:

FIG. 1 shows a III-V group semiconductor light emitting device; and

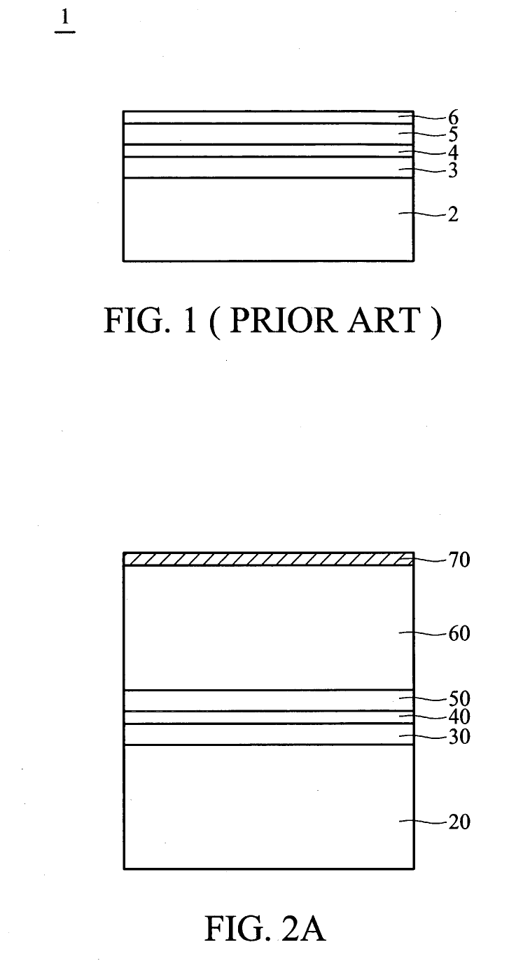

FIGS. 2A to 2C show the fabricating process of the first embodiment in the present invention.

### DETAILED DESCRIPTION OF THE INVENTION

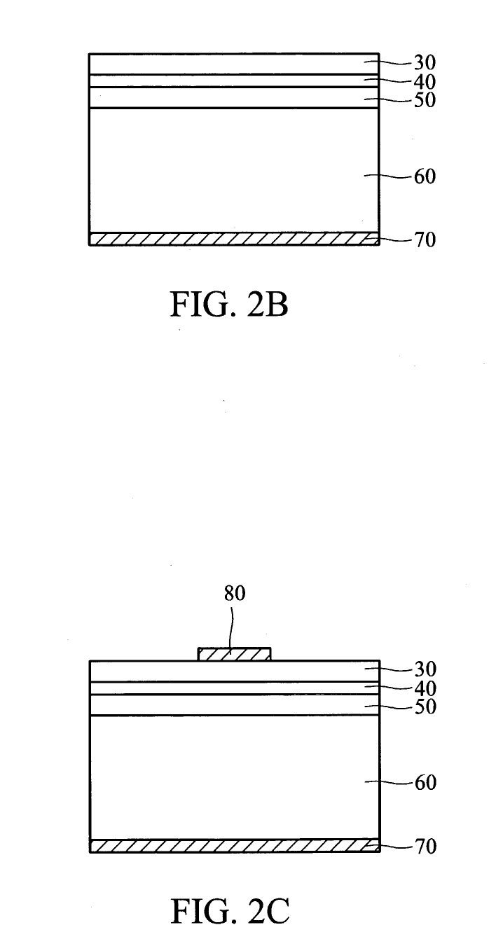

FIGS. 2A to 2C show the fabricating process of the first embodiment in the present invention. First, as in FIG. 2A, a GaAs substrate 20 is provided. The substrate herein can be also spinnel, SiC, or sapphire. Then, a n-type epitaxial layer 30 is formed on the GaAs subsrate 20 by, for example, molecular beam epitaxy (MBE) or metal-organic chemical vapor deposition (MOCVD). The n-type epitaxial layer 30 is Si- or Te-doped AlₓGa₁₋ₓAs (0≦x≦1) or AlₓGa₁₋ₓInP (0≦X≦1). An active layer 40 of double heterostructure or quantum well structure is then formed on the n-type epitaxy layer 30. The active layer 40 is, for example, AlₓGa₁₋ₓInP (0≦X≦1) Then a p-type epitaxial layer 50 is formed on the active layer 40 by, for example, MBE or MOCVD. The p-type epitaxial layer 50 is, for example, Zn- or Mg-doped p-type AlₓGa₁₋ₓInP (0≦X≦1). Then a p-type epitaxial layer 60 is formed on the p-type epitaxial layer 50 by liquid phase epitaxy (LPE), vapor phase epitaxy (VPE) or metal organic vapor phase epitaxy (MOVPE). The p-type epitaxial layer 60 can be formed by wafer-bonding as well, bonding the p-type epitaxial layer 60 to the p-type epitaxial layer 50 by applying high pressure at high temperature. Preferably, before performing the bonding step, the p-type epitaxial layer 60 is pre-treated by In diffusion, and the bonding temperature is between 200-2000 psi, the temperature is between 300-1200° C. The p-type epitaxial layer 60 is, for example, Zn- or Mg-doped p-type GaₓIn₁₋ₓP (0≦X≦1), preferably GaP, with a thickness between 10-150 μm. Conventionally, the p-type epitaxial layer 60 serves as a current-spreading layer with a thickness between 1-350 μm. In the present invention, however, the p-type epitaxial layer 60 serves as the transparent substrate of the LED, thus the thickness must be greater than that of conventional LED to avoid contamination by silver paste in the LED sealing process. Then a p-type ohmic contact layer 70 is formed on the p-type epitaxial layer 60.

The LED fabricated according to the above steps is then reversed, as in FIG. 2B, such that the LED is based on the transparent p-type epitaxial layer 60, i.e., the transparent substrate. The substrate 20 is removed by chemical etching or laser to expose the surface of the n-type epitaxial layer 30. A n-type ohmic contact layer 80 is then formed on the surface of the n-type epitaxial layer 30.

According to the method in the embodiment, an LED with a transparent substrate can be provided. The light emitted from the active layer can be extracted without being absorbed by the non-transparent substrate, thereby increasing the light emitting efficiency by as much as twice that of the LED with non-transparent substrate and improve the performance of opto-electronic devices.

FIG. 2C shows the LED structure in the embodiment, which comprises a transparent p-type epitaxial layer 60 as the substrate, wherein a GaP layer with a thickness of 70 μm, a p-type epitaxial layer 50 of Zn- or Mg-doped p-type AlₓGa₁₋ₓInP (0≦X≦1) is formed on the p-type epitaxial layer 60, an active layer of AlₓGa₁₋ₓInP (0≦X≦1) is formed on the p-type epitaxial layer 50, a n-type epitaxial layer 30 of Si- or Te-doped AlₓGa₁₋ₓAs (0≦x≦1) or AlₓGa₁₋ₓInP (0≦X≦1) is formed on the active layer 40, a n-type ohmic contact layer 80 formed on the n-type epitaxial layer 30 and a p-type ohmic contact layer 70 formed beneath the transparent p-type epitaxial layer 60.

The above mentioned n-type epitaxial layer 30 and n-type ohmic contact layer 80 can be p-type; meanwhile the p-type epitaxial layer 50, p-type epitaxial layer 60 and p-type ohmic contact layer 70 can be n-type.

While the invention has been described by way of example and in terms of the preferred embodiments, it is to be understood that the invention is not limited to the disclosed embodiments. On the contrary, it is intended to cover various modifications and similar arrangements as would be apparent to those skilled in the art. Thus, the scope of the appended claims should be accorded the broadest interpretation so as to encompass all such modifications and similar arrangements.

What is claimed is:

1. A method for fabricating a light-emitting diode with a transparent substrate, comprising:
forming a first type cladding layer on a substrate;
forming an active layer on the first type cladding layer;
forming a second type cladding layer on the active layer;
forming a second type transparent semiconductor layer on the second type cladding layer to serve as the transparent substrate;
removing the substrate; and
forming a first type contact layer on the surface of the first type cladding layer previously connected to the substrate.

2. A method for fabricating a light-emitting diode with a transparent substrate as claimed in claim 1, wherein the substrate is AsGa, SiC, spinnel or sapphire.

3. A method for fabricating a light-emitting diode with a transparent substrate as claimed in claim 1, wherein the first type cladding layer is AlₓGa₁₋ₓAs (0≦x≦1) or AlₓGa₁₋ₓInP (0≦X≦1).

4. A method for fabricating a light-emitting diode with a transparent substrate as claimed in claim 1, wherein the active layer is AlₓGa₁₋ₓInP (0≦X≦1).

5. A method for fabricating a light-emitting diode with a transparent substrate as claimed in claim 1, wherein the second type cladding layer is AlₓGa₁₋ₓInP (0≦X≦1).

6. A method for fabricating a light-emitting diode with a transparent substrate as claimed in claim 1, wherein the second type transparent semiconductor layer is GaP.

7. A method for fabricating a light-emitting diode with a transparent substrate as claimed in claim 1, wherein the thickness of the second type transparent semiconductor layer is between 10˜150 μm.

8. A method for fabricating a light-emitting diode with a transparent substrate as claimed in claim 1, wherein the first type is n-type and the second type is p-type.

9. A method for fabricating a light-emitting diode with a transparent substrate as claimed in claim 1, wherein the first type is p-type and the second type is n-type.

10. A method for fabricating a light-emitting diode with a transparent substrate as claimed in claim 1, wherein the second type transparent semiconductor layer is formed by LPE, VPE, or MOVPE.

11. A method for fabricating a light-emitting diode with a transparent substrate as claimed in claim 1, wherein the second type transparent semiconductor layer is formed by wafer-bonding.

12. A method for fabricating a light-emitting diode with a transparent substrate, comprising:
forming a first type cladding layer on a GaAs substrate;
forming an active layer on the first type cladding layer;
forming a second type cladding layer on the active layer;
forming a second type GaP layer on the second type cladding layer to serve as the transparent substrate;
forming a second type contact layer on the second type GaP layer;
removing the GaAs substrate; and
forming a first type contact layer on the surface of the first type cladding layer previously connected to the GaAs substrate.

13. A method for fabricating a light-emitting diode with a transparent substrate as claimed in claim 12, wherein the first type cladding layer is AlₓGa₁₋ₓAs (0≦x≦1) or AlₓGa₁₋ₓInP (0≦X≦1).

14. A method for fabricating a light-emitting diode with a transparent substrate as claimed in claim 12, wherein the active layer is AlₓGa₁₋ₓInP (0≦X≦1).

15. A method for fabricating a light-emitting diode with a transparent substrate as claimed in claim 12, wherein the second type cladding layer is AlₓGa₁₋ₓInP (0≦X≦1).

16. A method for fabricating a light-emitting diode with a transparent substrate as claimed in claim 12, wherein the thickness of the second type GaP layer is between 10˜150 μm.

17. A method for fabricating a light-emitting diode with a transparent substrate as claimed in claim 12, wherein the first type is n-type and the second type is p-type.

18. A method for fabricating a light-emitting diode with a transparent substrate as claimed in claim 12, wherein the first type is p-type and the second type is n-type.

19. A method for fabricating a light-emitting diode with a transparent substrate as claimed in claim 12, wherein the second type GaP layer is formed by LPE, VPE, or MOVPE.

20. A method for fabricating a light-emitting diode with a transparent substrate as claimed in claim 12, wherein the second type GaP layer is formed by wafer-bonding.
